(19) United States
(12) Patent Application Publication
(10) Pub. No.: US 2015/0183976 A1
(43) Pub. Date: Jul. 2, 2015

(54) TOUGHENING MASTERBLENDS

(71) Applicant: Dow Global Technologies LLC, Midland, MI (US)

(72) Inventors: Lameck Banda, Manvel, TX (US); Mark B. Wilson, Clute, TX (US); Robert L. Hearn, Lake Jackson, TX (US); Michael J. Mullins, Houston, TX (US)

(73) Assignee: DOW GLOBAL TECHNOLOGIES LLC, Midland, MI (US)

(21) Appl. No.: 14/416,385

(22) PCT Filed: Nov. 1, 2012
(86) PCT No.: PCT/US12/62939

§ 371 Date: Jan. 22, 2015

Related U.S. Application Data
(60) Provisional application No. 61/698,091, filed on Sep. 7, 2012.

(51) Int. Cl. C08L 33/12; C09D 109/06; H05K 1/03; C09J 109/06; C09J 133/12; C08L 9/06; C09D 133/12

(52) U.S. Cl. CPC C08L 33/12; C08L 9/06; C09D 109/06; C09D 133/12; C09J 109/06; C09J 133/12; H05K 1/0353

(57) ABSTRACT

A masterblend comprising a solvent and a core shell rubber which is formed by dispersing a core shell rubber in the solvent in a dispersion zone is disclosed. The masterblend can then be admixed with a thermosetting resin to form a curable composition.

### REFERENCE TO RELATED APPLICATIONS

The present application claims the benefit of U.S. Provisional Application No. 61/698,091, filed on Sep. 7, 2012.

### FIELD OF THE INVENTION

This invention is related to thermosetting resins. More specifically, this invention is related to the use of toughening formulations in thermosetting resins.

### BACKGROUND OF THE INVENTION

Epoxy resins are one of the most widely used engineering resins, and are well-known for their use in electrical laminates. Epoxy resins have been used as materials for electrical/electronic equipment, such as materials for electrical laminates because of their superiority in heat resistance, chemical resistance, insulation property, dimensional stability, adhesiveness and the like.

It is known to make electrical laminates and other composites from an epoxy-containing matrix resin and a fibrous reinforcement.

Phenolic cure chemistry is used for lead-free solder materials to improve the thermal stability (increase the glass transition and thermal decomposition temperatures (Tg and Td)) of epoxy-based electrical laminate formulations. This is due to the fact that phenolic hardeners increase the molecular rigidity between crosslinks thus increasing both the glass transition and thermal decomposition temperatures. However, increased rigidity between crosslinks imparts significant brittleness to the resin matrix. The brittleness is important because it affects part-fabrication and reliability. In the fabrication of electronic parts such as printed circuit boards, holes are drilled into the copper-clad multi-ply boards and later the drilled holes are plated with copper. Mechanical drilling of these holes causes defects like cracks, delamination, and debonding in a brittle laminate board. Furthermore, the drilling of brittle laminates results in high drill bit wear and breakage. Because the drilling process is a very expensive step in the device fabrication protocol, drilling parameters are optimized to obtain high quality drill-holes and to minimize drill bit wear. The challenge arises from the fact that engineering process changes have not been successful in reducing drilling defects without significantly influencing the economics. Therefore, there is a need for additives to improve resin toughness.

### SUMMARY OF THE INVENTION

In an embodiment of the present invention, there is disclosed a masterblend comprising, consisting of, or consisting essentially of a) a solvent; and b) a core shell rubber.

In another embodiment of the present invention, there is disclosed a process comprising, consisting of, or consisting essentially of a) dispersing a core/shell rubber in a solvent to form a masterblend; and b) admixing the masterblend with a thermosetting resin to form a curable composition.

### DETAILED DESCRIPTION

In an embodiment of the invention, there is disclosed a masterblend comprising, consisting of, or consisting essentially of a) a solvent; and b) a core shell rubber.

Solvent

Any solvent suitable for laminate formulations can be used. Non-limiting examples of suitable solvents include ketones, alcohols, water, glycol ethers, aromatic hydrocarbons and mixtures thereof. Preferred solvents include but are not limited to methyl ethyl ketone, acetone, Dowanol™ PM (mixture of 1-hydroxy-2-methoxypropane and 1-methoxy-2-hydroxypropane), cyclohexanone, Dowanol™ PMA (mixture of 1-acetoxy-2-methoxypropane and 1-methoxy-2-acetoxypropane), dimethylformamide (DMF), methyl isobutyl ketone (MIBK), xylene, toluene, methanol, and butanol. Combinations of any two or more solvents can also be used.

### Core Shell Rubber

Generally the core shell rubber has a styrene butadiene core and/or a methyl methacrylate shell. In an embodiment, the core does not swell in the solvent.

Examples of core shell rubbers that can be used include, but are not limited to those in which the shell is methyl methacrylate, methyl methacrylate/ethyl acrylate, styrene/acrylonitrile, methyl methacrylate/ethyl acrylate/styrene, and the core is butadiene, butadiene/styrene, butyl acrylate, and combinations of any two or more thereof.

In an embodiment, the masterblend comprises from 5 weight percent to 40 weight percent, core shell rubber, based on the total weight of the masterblend. The masterblend comprises in the range of from 10 weight percent to 30 weight percent core shell rubber in another embodiment, and from 15 weight percent to 30 weight percent in yet another embodiment. In yet another embodiment, the masterblend comprises about 30 weight percent core shell rubber.

In another embodiment of the invention, there is disclosed a process comprising, consisting of, or consisting essentially of: a) dispersing a core shell rubber in a solvent in a dispersion zone to form a masterblend; and b) admixing the masterblend with a thermosetting resin to form a curable composition.

Dispersion

The core shell rubber can be dispersed in the solvent using any suitable method to form the masterblend.

The dispersion zone can comprise any suitable high shear mixing method. In an embodiment, the mixing set-up that is applied to make the dispersion has oxygen monitoring and nitrogen purging and the capability to provide an inert atmosphere for the dispersion vessel during loading of the core shell rubber and during mixing. This embodiment is useful for core shell rubbers having low minimum ignition energy being dispersed in volatile solvents. For these core shell rubbers, the potential for dust explosion must be considered.

Various pieces of mixing equipment and processes can be utilized to make the dispersion. These include, but are not limited to, high shear mixers, static mixers, rotor-stators, ultrasonics, colloid mills, liquid whistles, valve homogenizers, and agitated vessels. In an embodiment, any mixing equipment selected must generate a power per unit mass of at least 0.5 W/Kg, more than 8 W/Kg in another embodiment, and more than 13 W/Kg in yet another embodiment. Power input of about 13 W/Kg breaks down agglomerates of the solid to about 10 microns and less. Low power input (<13 W/Kg) can result in large agglomerates of 50 microns of the solid, whereas higher power input (>13 W/Kg) can result in high temperature build-up resulting in the loss of solvent, and a waste of energy. In an embodiment, optional cooling can help reduce the vapor pressure of the solvent and can therefore reduce solvent loss. Also, for any of the mixing techniques chosen, the unit operation to be used can either be a continuous or batch process.

The various types of mixers that can be used in embodiments of the present invention encompass a wide variety of design geometries and many adjustable parameters that can be optimized for specific applications. The primary components for a mixing system are the solid and liquid feed systems and the mixing vessel. To disperse the solid in the liquid, the liquid can be pre-loaded in the mixing vessel and the solid component fed slowly under continuous mixing. In an alternative process, the mixing can be performed by adding both the liquid and solid components to the mixing vessel in the appropriate ratio prior to mixing. In yet another process, the liquid and solid components can be pre-soaked or pre-mixed in either a separate holding tank or in the mixing vessel prior to being subjected to high shear mixing in the mixing vessel. These processes can be run in either continuous or batch processes depending on equipment design or quantity required.

Thakur, R. K., Vial, Ch., Nigam, K. D. P., Nauman, E. D., Djelveh, G., Static Mixers in the Process Industries—A Review, Trans IChemE. Vol 81, Part A (2003) presents a review of the various static mixers used in the process industries. The design and limitations of these mixers are discussed and the key parameters needed for the selection of a suitable mixer for mixing of miscible liquids, liquid-liquid and gas-liquid interface generation, liquid solid dispersion are also presented. Zhang, J., Xu, S., Li, W., High Shear Mixers: A Review of Typical Applications and Studies on Power Draw, Flow Pattern, Energy Dissipation and Transfer Properties, Chemical Engineering and Processing 57-58 (2012) 25-41 presents a review on high shear mixers focusing on typical applications and studies on power draw, flow pattern, energy dissipation and transfer properties. Typical applications of high shear mixers with regard to solid-liquid suspension, liquid-liquid emulsification, and chemical reactions. Another example of an apparatus for mixing solid and liquid substances can be found in U.S. Pat. No. 4,448,589. The apparatus comprises a loop-type reactor housing having inlet means at one end and outlet means at the opposite end with a tube socket for introducing the substances into the reactor. Another system for mixing a liquid material and a solid material is disclosed in European Patent Application EP 1 745 840 A1. This system comprises: (i) a base unit, wherein flows the liquid material and the solid material; (ii) a liquid material supply; (iii) a solid material supply; (iv) a liquid/solid mixing output, and (v) an injection means connected to the liquid material supply and to the solid material supply. Any of the above mixing systems can be used in embodiments of the present invention.

The masterblend can then be admixed with a thermosetting resin to form a curable composition. Thermosetting resins can include but are not limited to epoxy resins, cyanate esters, vinyl esters, polycyanurates, phenolic resins, polyurethanes, and polyimides.

In an embodiment, the thermosetting resin is an epoxy resin.

The epoxy resins used in embodiments disclosed herein may include conventional and commercially available epoxy resins, which may be used alone or in combinations of two or more, including, for example, novolac resins, isocyanate modified epoxy resins, and carboxylate adducts, among others. In choosing epoxy resins for compositions disclosed herein, consideration should not only be given to properties of the final product, but also to viscosity and other properties that may influence the processing of the resin composition.

The epoxy resin component may be any type of epoxy resin useful in molding compositions, including any material containing one or more reactive oxirane groups, referred to herein as “epoxy groups” or “epoxy functionality.” Epoxy resins useful in embodiments disclosed herein may include mono-functional epoxy resins, multi- or poly-functional epoxy resins, and combinations thereof. Monomeric and polymeric epoxy resins may be aliphatic, cycloaliphatic, aromatic, or heterocyclic epoxy resins. In an embodiment, the epoxy resins include, but are not limited to glycidyl ethers, cycloaliphatic resins, epoxidized oils, and so forth Specific examples include the condensation products of bisphenol A diglycidyl ether with bisphenol A, tetrabromobisphenol A or the condensation products of the diglycidyl ether of tetrabromobisphenol A with bisphenol A or tetrabromobisphenol A. Commercial examples include, but are not limited to D.E.R.™ 592 and D.E.R.™ 593, each available from The Dow Chemical Company, Midland Mich. It is common to add the glycidyl ethers of bisphenols, novolacs (polyphenols derived from condensation of formaldehyde or other aldehyde with a phenol). Specific examples include tetrabromobisphenol A, the novolacs of phenol, cresol, dimethylphenols, p-hydroxybiphenyl, naphthol, and bromophenols, various oligomeric resins.

Other commercial examples include D.E.R.™ 331 (bisphenol A liquid epoxy resin) and D.E.R.™ 332 (diglycidyl ether of bisphenol A), D.E.R.™ 592 (a flame retardant brominated epoxy resin), a flame retardant brominated bisphenol type epoxy resin available under the tradename D.E.R.™ 560, 1,4-butanediol diglycidyl ether of phenol formaldehyde novolac (such as those available under the tradenames D.E.N.™ 431 and D.E.N.™ 438. The D.E.N.™ and D.E.R.™ products are available from The Dow Chemical Company, Midland, Mich. Mixtures of any of the above-listed epoxy resins may, of course, also be used.

The compositions in the above-described embodiments can be used to produce varnishes. In addition to an epoxy resin, a varnish can also contain curing agents, hardeners, catalysts, flame retardants, synergists, additives, and inert fillers.

Hardeners/Curing Agents

A hardener or curing agent may be provided for promoting crosslinking of the curable composition. The hardeners and curing agents may be used individually or as a mixture of two or more. In some embodiments, hardeners may include dicyandiamide (dicy) or phenolic curing agents such as novolacs, resoles, and bisphenols. Anhydrides such as poly(styrene-comaleic anhydride) may also be used.

Curing agents may also include primary and secondary polyamines and adducts thereof, anhydrides, and polyamides. For example, polyfunctional amines may include aliphatic amine compounds such as diethylene triamine (D.E.H.™ 20, available from The Dow Chemical Company, Midland, Mich.), triethylene tetramine (D.E.H.™ 24, available from The Dow Chemical Company, Midland, Mich.), tetraethylene pentamine (D.E.H.™ 26, available from The Dow Chemical Company, Midland, Mich.), as well as adducts of the above amines with epoxy resins, diluents, or other amine-reactive compounds. Aromatic amines, such as metaphenylene diamine and diamine diphenyl sulfone, aliphatic polyamines, such as amino ethyl piperazine and polyethylene polyamine, and aromatic polyamines, such as metaphenylene diamine, diamino diphenyl sulfone, and diethyltoluene diamine, may also be used.

Anhydride curing agents may include, for example, nadic methyl anhydride, hexahydrophthalic anhydride, trimellitic anhydride, dodecenyl succinic anhydride, phthalic anhydride, methyl hexahydrophthalic anhydride, tetrahydrophthalic anhydride, and methyl tetrahydrophthalic anhydride, among others.

The hardener or curing agent may include a phenol-derived or substituted phenol-derived novolac or an anhydride. Non-limiting examples of suitable hardeners include phenol novolac hardener, cresol novolac hardener, dicyclopentadiene bisphenol hardener, limonene type hardener, anhydrides, and mixtures thereof.

In other embodiments, curing agents may include dicyandiamide, boron trifluoride monoethylamine, and diaminocyclohexane. Curing agents may also include imidazoles, their salts, and adducts. Other curing agents include phenolic, benzoxazine, aromatic amines, amido amines, aliphatic amines, anhydrides, and phenols.

Catalysts

Optionally, catalysts may be added to the curable compositions described above. Catalysts may include, but are not limited to, imidazole compounds including compounds having one imidazole ring per molecule, such as imidazole, 2-methylimidazole, 2-ethyl-4-methylimidazole, 2-undecylimidazole, 2-heptadecylimidazole, 2-phenylimidazole, 2-phenyl-4-methylimidazole, 1-benzyl-2-methylimidazole, 2-ethylimidazole, 2-isopropylimidazole, 2-phenyl-4-benzylimidazole, 1-cyanoethyl-2-methylimidazole, 1-cyanoethyl-2-ethyl-4-methylimidazole, 1-cyanoethyl-2-undecylimidazole, 1-cyanoethyl-2-isopropylimidazole, 1-cyanoethyl-2-phenylimidazole, 2,4-diamino-6-[2′-methylimidazolyl-(1)]-ethyl-s-triazine, 2,4-diamino-6-[2′-ethyl-4-methylimidazolyl-(1)]-ethyl-s-triazine, 2,4-diamino-6-[2′-undecylimidazolyl-(1)]-ethyl-s-triazine, 2-methyl-imidazo-lium-isocyanuric acid adduct, 2-phenylimidazolium-isocyanuric acid adduct, 1-aminoethyl-2-methylimidazole, 2-phenyl-4,5-dihydroxymethylimidazole, 2-phenyl-4-methyl-5-hydroxymethylimidazole, 2-phenyl-4-benzyl-5-hydroxymethylimidazole and the like; and compounds containing 2 or more imidazole rings per molecule which are obtained by dehydrating above-named hydroxymethyl-containing imidazole compounds such as 2-phenyl-4,5-dihydroxymethylimidazole, 2-phenyl-4-methyl-5-hydroxymethylimidazole and 2-phenyl-4-benzyl-5-hydroxy-methylimidazole; and condensing them with formaldehyde, e.g., 4,4′-methylene-bis-(2-ethyl-5-methylimidazole), and the like.

In other embodiments, suitable catalysts may include amine catalysts such as N-alkylmorpholines, N-alkylalkanolamines, N,N-dialkylcyclohexylamines, and alkylamines where the alkyl groups are methyl, ethyl, propyl, butyl and isomeric forms thereof, and heterocyclic amines.

Flame Retardants

The curable composition can also contain a flame retardant. In an embodiment, the flame retardant is a brominated flame retardant. Examples of brominated flame retardants include, but are not limited to brominated polyphenols such as, for example, tetrabromobisphenol A (TBBA) and tetrabromobisphenol F and materials derived therefrom: TBBA-diglycidyl ether, reaction products of bisphenol A or TBBA with TBBA-diglycidyl ether, and reaction products of bisphenol A diglycidyl ether with TBBA.

In another embodiment, the flame retardant is a non-halogen flame retardant. In an embodiment, the non-halogen flame retardant can be a phosphorus-containing compound. The phosphorus-containing compound can contain some reactive groups such as a phenolic group, an acid group, an amino group, an acid anhydride group, a phosphate group, or a phosphinate group which can react with the epoxy resin or hardener of the composition.

The phosphorus-containing compound can contain on average one or more than one functionality capable of reacting with epoxy groups. Such phosphorus-containing compound generally contains on average 0.8 to 5 functionalities. In an embodiment, the phosphorus-containing compound contains in the range of from 0.9 to 4 functionalities, and in another embodiment, it contains in the range of 1 to 3 functionalities capable of reacting with an epoxy resin.

Phosphorus-containing compound useful in the present invention include for example one or more of the following compounds: P-H functional compounds such as for example HCA, dimethylphosphite, diphenylphosphite, ethylphosphonic acid, diethylphosphinic acid, methyl ethylphosphinic acid, phenyl phosphonic acid, vinyl phosphonic acid, phenolic (HCA-HQ); tris(4-hydroxyphenyl)phosphine oxide, bis(2-hydroxyphenyl)phenylphosphine oxide, bis(2-hydroxyphenyl)phenylphosphinate, tris(2-hydroxy-5-methylphenyl)phosphine oxide, acid anhydride compounds such as M-acid-AH, and amino functional compounds such as for example bis(4-aminophenyl)phenylphosphate, and mixtures thereof. In an embodiment, a phosphonate compound can be used. Phosphonates that also contain groups capable of reacting with the epoxy resin or the hardener such as polyglycidyl ethers or polyphenols with covalently-bound tricyclic phosphonates are useful. Examples include but are not limited to the various materials derived from DOP (9,10-dihydro-9-oxa-10-phosphaphenanthrene 10-oxide) such as DOP-hydroquinone (10-(2′,5′-dihydroxyphenyl)-9,10-dihydro-9-oxa-10-phosphaphenanthrene 10-oxide), condensation products of DOP with glycidylether derivatives of novolacs, and inorganic flame retardants such as aluminum trihydrate, aluminum hydroxide (Boehmite) and aluminum phosphinite. If inorganic flame retardant fillers are used, silane treated grades are preferred.

Mixtures of one or more of the above described flame retardant compounds may also be used.

Additional Optional Components

The compositions disclosed herein can optionally include synergists, and conventional additives and inert fillers. Synergists can include, for example, magnesium hydroxide, zinc borate, and metallocenes), solvents (e.g., acetone, methyl ethyl ketone, and DOWANOL™ PMA). Additives and inert fillers can include, for example, silica, alumina, glass, talc, metal powders, titanium dioxide, wetting agents, pigments, coloring agents, mold release agents, coupling agents, ion scavengers, UV stabilizers, flexibilizing agents, and tackifying agents. Additives and fillers can also include fumed silica, aggregates such as glass beads, polytetrafluoroethylene, polyol resins, polyester resins, phenolic resins, graphite, molybdenum disulfide, abrasive pigments, viscosity reducing agents, boron nitride, mica, nucleating agents, and stabilizers, among others. Fillers can include functional or non-functional particulate fillers that may have a particle size ranging from 0.5 nm to 100 microns and may include, for example, alumina trihydrate, aluminum oxide, aluminum hydroxide oxide, metal oxides, and nano tubes). Fillers and modifiers can be preheated to drive off moisture prior to addition to the epoxy resin composition. Additionally, these optional additives can have an effect on the properties of the composition, before and/or after curing, and should be taken into account when formulating the composition and the desired reaction product. Silane treated fillers can also be used.

The prepreg can be obtained by a process that includes impregnating a matrix component into a reinforcement component. The matrix component surrounds and/or supports the reinforcement component. The disclosed curable compositions/varnishes can be used for the matrix component. The matrix component and the reinforcement component of the prepreg provide a synergism. This synergism provides that the prepregs and/or products obtained by curing the prepregs have mechanical and/or physical properties that are unattainable with only the individual components.

The reinforcement component can be a fiber. Examples of fibers include, but are not limited to, glass, aramid, carbon, polyester, polyethylene, quartz, metal, ceramic, biomass, and combinations thereof. The fibers can be coated. An example of a fiber coating includes, but is not limited to, boron.

Impregnating the matrix component into the reinforcement component may be accomplished by a variety of processes. The prepreg can be formed by contacting the reinforcement component and the matrix component via rolling, dipping, spraying, or some other procedure. After the prepreg reinforcement component has been contacted with the prepreg matrix component, the solvent can be removed via volatilization. While and/or after the solvent is volatilized the prepreg matrix component can be cured, e.g. partially cured. This volatilization of the solvent and/or the partial curing can be referred to as B-staging. The B-staged product can be referred to as the prepreg. For some applications, B-staging can occur via an exposure to a temperature of 60° C. to 250° C.; for example B-staging can occur via an exposure to a temperature from 65° C. to 240° C., or 70° C. to 230° C. For some applications, B-staging can occur for a period of time of 1 minute to 60 minutes; for example B-staging can occur for a period of time from, 2 minutes to 50 minutes, or 5 minutes to 40 minutes. However, for some applications the B-staging can occur at another temperature and/or another period of time.

One or more of the prepregs may be cured, e.g. more fully cured, to obtain a product. The prepregs can be layered or/and formed into a shape before being cured further. For some applications, e.g. when an electrical laminate is being produced, layers of the prepreg can be alternated with layers of a conductive material. An example of the conductive material includes, but is not limited to, copper foil. The prepreg layers can then be exposed to conditions so that the matrix component becomes more fully cured.

One example of a process for obtaining the more fully cured product is pressing. One or more prepregs may be placed into a press where it subjected to a curing force for a predetermined curing time interval to obtain the more fully cured product. The press may have a curing temperature of 80° C. to 250° C.; for example the press may have a curing temperature of 85° C. to 240° C., or 90° C. to 230° C. For one or more embodiments, the press has a curing temperature that is ramped from a lower curing temperature to a higher curing temperature over a ramp time interval.

During the pressing, the one or more prepregs can be subjected to a curing force via the press. The curing force may have a value that is 5 pounds per square inch (psi) to 50 psi; for example the curing force may have a value that is 10 psi to 45 psi, or 15 psi to 40 psi. The predetermined curing time interval may have a value that is 5 seconds(s) to 500 s; for example the predetermined curing time interval may have a value that is 25 s to 540 s, or 45 s to 520 s. For other processes for obtaining the product other curing temperatures, curing force values, and/or predetermined curing time intervals are possible. Additionally, the process may be repeated to further cure the prepreg and obtain the product.

The varnishes disclosed herein can be used in the manufacture of electrical laminates, which can then be used in the manufacture of printed circuit boards. Additional uses for the compositions disclosed herein include, but are not limited to coatings, composites, castings, and adhesives.

### EXAMPLES

### Test Methods

### Scanning Electron Microscopy (SEM)

SEM images were obtained using a FEI Nova 600 Schottky field emission SEM equipped with a Bruker 4030 X-Flash SDD spectrometer and Esprit 1.8 software. Laminate coupons were embedded and polished using a Leco Spectrum System 1000 polishing wheel to reveal the cross section. Neat epoxy resin plaques were polished using a diamond knife to expose a cross-section. Once polished, the cross-sections were mounted on aluminum SEM stubs using carbon tape and carbon paint, and were subsequently sputter coated with iridium. Microscope conditions were 5 kV, spot size 5, and a working distance between 5 and 10 mm. The solid state backscatter detector was used.

### Glass Transition Temperature

The glass transition temperature was measured by differential scanning calorimetry (DSC) on a dual cell TA Instruments Q200. Approximately 10 mg of sample were subjected to two consecutive temperature ramps at 10° C./min from ambient to 250° C. Exothermic activity on the first scan was closely followed to ensure a full cure. The sample was then subjected to a third ramp at 20° C./min and T_{g} was determined using the half-height point. Therefore, the laminate experienced additional cure in the DSC evaluation which was not used before the physical property testing.

### Decomposition Temperature

A Thermal Gravimetric Analyzer (TGA), TA Instruments Q5000, was used to determine the decomposition temperature (T_{d}) of the samples. T_{d} was determined as the temperature at which the sample experienced a 5% weight loss. About 25 mg of sample were ramped at a rate of 10° C./min to 550° C. TGA was also used to evaluate residual solvent.

### Thermal Expansion

A Thermal Mechanical Analyzer (TMA), TA Instruments Q400, was used to measure the coefficient of linear thermal expansion (CLTE) below and above T_{g}. Copper clad laminate samples were cut into ˜6 mm×˜6 mm squares using a water cooled diamond tile saw. CLTE (<T_{g} and >T_{g}) was obtained from the slope of the thermogram below and above T_{g}. The TMA was also used to determine the time to delamination at 288° C. (T288). The time to delamination was determined as the elapsed time from when the temperature reached 288° C. to when a sudden irreversible dimensional change occurred.

### Interlaminar Fracture Toughness

The standard dual cantilever beam geometry was used to evaluate interlaminar fracture toughness using the ASTM standard D-5528. Samples were prepared from double-thick 16-ply unclad laminates to enhance the bending stiffness. A crack initiator for the fracture test was facilitated by a thin sheet of Mylar™ that was inserted from one edge (about 2.5 inches) in the middle of the lay-up during stacking of the prepregs prior to consolidation. After consolidating and curing the laminate in the press, a wet circular saw was used to cut test specimens that were approximately 1 inch wide and 11 inches long. Metallic blocks were glued to the primed specimens using a two-part Plexus methacrylate adhesive. The blocks were held to the specimens using a C-clamp and allowed to sit overnight for the adhesive to cure. For the fracture test, the samples were gripped on a MTS 810 servo-hydraulic test frame using hinges that accommodated the blocks. A dowel pin was used to hold the specimen in place during the experiment. The samples were loaded at a fixed rate of 0.2 in/min and during the test, both load and stroke signals were recorded using a computer controlled data acquisition system. Samples were loaded until the total crack length reached 45 mm.

### Fracture Toughness

The critical stress intensity factor K_{IC} tests were performed using a pre-cracked specimen in the compact tension configuration according to ASTM D5045. Test specimens with a length of 27 mm, a width of 27 mm and a thickness of 4 mm were machined from 6 mm thick cured plaques. Two holes of 5.0 mm diameter were drilled in the specimen at the loading points. A deep notch was first cut into the center of the specimen. A fresh razor blade, which had been chilled in liquid nitrogen, was then tapped into the notch with a hammer to create a sharp pre-crack front in the specimens.

The samples were then loaded in to the test frame. The fracture toughness values K_{IC} of the cured bulk resins in compact tension geometry were calculated from the following relationship:

$${K}_{IC} = ( \frac{P}{{BW}^{1 / 2}} ) f ( \frac{a}{W} )$$

where f (a/W) is a geometric correction factor which is a function of the ratio of the crack length to specimen width and for the compact tension geometry is defined as:

f(a/W)=(2+a/W){0.886+4.64a/W−13.32(a/W)²+14.72(a/W)³−5.6(a/W)⁴}/(1−a/W)^{2/3}.

P, a, B, and W respectively represent the maximum load, crack length, thickness, and width of the specimen.

### Moisture Uptake and Solder Dip

The moisture uptake was determined by putting pre-weighed 2″×3″ coupons of laminates in an autoclave at 122° C. for 2 h. The coupons were then removed from the autoclave, cleaned and re-weighed. The weight difference between the pre-autoclave and post-autoclave samples scaled by the initial weight of the coupons was determined as the percentage moisture uptake. The conditioned samples were then dipped into the 288° C. solder for 20 seconds and visually inspected for blistering and delamination.

### Example 1

### Solubility of Core Shell Rubbers

Several core shell rubbers were evaluated for their solubility. Table 1 shows a summary of these modifiers in MEK.

TABLE 1

| | | | | | Modifier | |
|---|---|---|---|---|---|---|
| | Func- | | | Solvent | addition | Swelling |
| Modi- | tional- | Core/Shell | Primary | system | level | in |
| fier | ization | ratio (%) | PS (nm) | used | (wt %) | solvent |
| A | No | 75/25 | 195 | MEK | 20% | No |
| B | No | 80/20 | 200 | MEK | 20% | No |
| C | No | 79/21 | 180 | MEK | 20% | No |
| D | No | 75/25 | 185 | MEK | 20% | No |
| E | Yes | 80/20 | 180 | MEK | 20% | Insoluble |
| F | Yes | 80/20 | 180 | MEK | 20% | Insoluble |
| G | No | 75/25 | 350 | MEK | 20% | Yes |
| H | No | 75/25 | 350 | MEK | 20% | Yes |
| I | No | Unknown | 600 | MEK | 20% | Yes |
| J | No | Unknown | 500 | MEK | 20% | Yes |
| K | Yes | 80/20 | 500 | MEK | 20% | Yes |
| L | No | Unknown | 170 | MEK | 20% | Yes |
| M | No | 47/53 | 100/600 | MEK | 20% | No |

The results show dispersion stability and impact on viscosity in MEK. The core shell rubbers that swelled in MEK precludes their application as tougheners for electrical laminates due to processing constraints. Use of excess solvent to reduce viscosity would result in poor loading of resin on glass. The dispersion of a toughener in solvent and their impact on viscosity are very important parameters on the suitability of a toughening material for electrical laminates because of processability problems.

### Example 2

### Preparation of Masterblend

Masterblends were prepared with 30% core shell rubber in methyl ethyl ketone according to the settings in Table 2, below. A Myer mixer was used.

TABLE 2

| | | | Batch 3 | | |
|---|---|---|---|---|---|
| | | | (Bulk pro- | | |
| | Batch 1 | Batch 2 | duction) | Batch 4 | Batch 5 |
| Impeller Diameter | 3 | 3 | 16 | 2.5 | 2.5 |
| (in) | | | | | |
| Vessel Diameter | 9 | 9 | 44 | 5.5 | 5.5 |
| (in) | | | | | |
| Impeller position | 76 | 76 | 200 | 15 | 25 |
| (mm) | | | | | |
| CSR Loading | 30 | 30 | 30 | 27 | 30 |
| (wt %) | | | | | |
| Stirring Speed | 750 | 1500 | 900 | 1000 | 2000 |
| (rpm) | | | | | |
| End batch time | 60 | 60 | 60 | 60 | 60 |
| (min) | | | | | |
| Ending viscosity | 500 | 500 | 500 | 25 | 190 |
| (cP) | | | | | |
| Reynolds No. | 140 | 280 | 4810 | 2960 | 778 |
| Tip speed (m/s) | 2.99 | 5.98 | 19.16 | 3.32 | 6.65 |
| Tip speed (ft/min) | 589.2 | 1176 | 3770 | 653 | 1309 |
| Max shear (s⁻¹) | 546 | 1240 | 1780 | 4810 | 8790 |
| Power/mass | 1.99 | 10.3 | | 2.91 | 58.1 |
| (W/Kg) | | | | | |
| Dispersion | Poor | Fewer | Good | Poor | Good |
| Quality | | agglomer- | | | |
| | | ates >10 um | | | |

### Example 3

### Laminates

A model high glass transition temperature formulation for electrical laminates was used as the base resin. This formulation consists of a high thermal stability resin D.E.N.™ 438, a brominated resin D.E.R.™ 560 and a phenolic hardener Resicure™ 3026.

Details of the formulation are shown in Table 3, below.

TABLE 3

| Components | Actual, Wt (g) |
|---|---|
| D.E.N ™438 A80 (80% NV* in acetone) | 8.1 |
| D.E.R ™560 | 3.41 |
| Resicure 3026 (solid) | 4.76 |
| CSR (20% in methylethylketone) | 2.94 |
| 2-methyl imidazole (20% NV* in Dowanol ™ PM) | 0.02 |
| Total | 19.23 |

(* non-volatiles)

### Varnish Preparation

The solids content of the final formulation was adjusted with methylethylketone to obtain a viscosity of “B” using Gardner bubble viscosity standards. The reactivity of the varnish was measured using the stroke cure test. A few grams of the sample were placed on a hot plate at 171° C. and stroked using a wooden popsicle stick. The elapsed time in seconds required for gelation, as indicated by a sudden increase in the viscosity, is the resin reactivity with a target of 300 seconds. The reactivity was adjusted accordingly by using 2-methylimidazole catalyst.

### Preparation of Prepregs

The prepregs were prepared using a Litzler Pilot Treater. The varnish system was impregnated on Hexcel 7628 woven glass and then passed through 30 ft of heated oven space in the treater. The oven temperature was 350° F. and the line speed was 5.5 ft/min. The prepreg was evaluated for gel time, resin loading and reactivity. Adjustments were made accordingly.

To determine the gel time of the prepreg, powder was crushed from the prepreg. Care was taken to ensure that there were no glass fibers in the powder. About 0.25 g of prepreg powder was placed on a hotplate at 171° C. and stroked using a wooden spatula. This is a qualitative measurement and the gel time was recorded as the elapsed time required for gelation. Typical prepreg gel times were about 90 seconds.

### Neat Casting Preparation

To make the neat resin castings, approximately 200 grams of varnish was poured in a Teflon® dish and placed into a vacuum oven for about 8 hours at 90° C. The dried ingredients were then ground into powder and sieved. The weight loss was measured via TGA. Platinum pans were used at a ramp rate of 25° C./min, from ambient temperature to 163° C., with an isothermal hold for 60 min. This step was repeated until the weight loss was less than 0.5% and the varnish reactivity was advanced to ˜75 s. The sieved powder was pressed in a mold using a Carver press at room temperature and compacted resulting in a 3″×3″×⅜″ thick coupon. The coupon was placed into a mold and pressed using a Tetrahedron hydraulic press observing the conditions in Table 4, below.

TABLE 4
The press cycle used in the fabrication of laminates

| Step | |
|---|---|
| 1 | Ramp 9° C./min to 329° F./7.6 psi/10 s. hold |
| 2 | Ramp 9° C./min to 392° F./150 psi/90 min. hold |
| 3 | Ramp 20° C./min to 90° F./150 psi/10 s. hold |

Tables 5 and 6 show thermomechanical properties of laminate coupons made from the epoxy resin formulation toughened with different materials compared with the non-toughened control. Comparisons are also made with laminate coupons made with core shell rubbers X, Y, and Z. CSR X has a butyl acrylate core and a methyl methacrylate shell, Y has a 36/64 core to shell ratio and has a butadiene/styrene core and a styrene/methyl methacrylate/aniline/glycidyl methacrylate shell, and Z has a polybutadiene core and a poly(styrene-co-acrylonitrile) shell.

TABLE 5
Thermomechanical properties of different toughenend resin
formulations compared with a non-toughenend control.

| CSR | Control | M | C | X | Y | Z |
|---|---|---|---|---|---|---|
| Loading Level (%) | 0 | 7.5 | 3.75 | 3.75 | 7.5 | 7.5 |
| Laminate Thickness | 1.50-1.70 | 1.73 | 1.37-1.60 | 1.50-1.58 | 1.40-1.60 | 1.43-1.58 |
| Tg1 (° C.) | 171 | 168 | 169 | n/a | 170 | 168 |
| Tg2 (° C.) | 173 | 169 | 169 | n/a | 171 | 168 |
| Tg3 (° C.) | 177 | 177 | 173 | 173 | 176 | 173 |
| Td (5% wt | 363 | 361 | 365 | 371 | 366 | 364 |
| loss) (° C.) | | | | | | |
| % resin | 42.1 | 42.5 | 41 | 46 | 47 | 42 |
| T260 (min) | n/d | n/d | >60 | >30 | >60 | n/d |
| CTE < Tg | n/d | n/d | 57.94 | 49.9 | 58 | 69 |
| CTE > Tg | n/d | n/d | 252.8 | 229.4 | 214 | 279 |
| T288 (min) | 43.1 | 41.5 | 26.2 | 20 | >30 | 32 |
| CTE < Tg | 60.3 | 50.1 | 35 | n/d | 53 | n/d |
| CTE > Tg | 260.3 | 203.6 | 228 | n/d | 236 | n/d |
| Cu Peel | 7.63 | 7.1 | 7.92 | 7.6 | 8.16 | 6.82 |
| Water Uptake (%) | 0.25 | 0.36 | 0.20 | 0.19 | 0.31 | 0.33 |
| Solder Dip | 100 | 100 | 100 | 100 | 100 | 100 |
| @550 F. (% Pass) | | | | | | |
| K1C (MPa · m^{0.5}) | 0.66 | 1.09 | 1.02 | 0.9 | 1.07 | n/d |
| G1C (kJ/m²) | 0.26 | 0.62 | 0.44 | n/d | 0.52 | 0.4 |
| UL94 rating | n/d | V-0 | V-0 | V-0 | n/d | n/d |

TABLE 6
Effect of the addition of defoaming
aids on thermomechanical properties.

| | | C w/ | | D w/ |
|---|---|---|---|---|
| | C | Defoamer | D | Defoamer |
| Laminate Thickness | 1.37-1.60 | 1.35-1.57 | 1.35-1.60 | 1.35-1.60 |
| Tg1 (° C.) | 169 | 164 | 165 | n/d |
| Tg2 (° C.) | 169 | 165 | 167 | 166 |
| Tg3 (° C.) | 173 | 168 | 168 | 169 |
| Td (° C.) (5% wt loss) | 365 | 367 | 366 | 359 |
| % resin | 41 | 38 | 40 | 38 |
| T260 (min) | >60 | >60 | >60 | >60 |
| CTE < Tg | 58 | 54 | 47 | 52 |
| CTE > Tg | 253 | 239 | 206 | 216 |
| T288 (min) | 26.2 | 21 | 21 | 20.8 |
| CTE < Tg | 35 | 65 | 57 | 41 |
| CTE > Tg | 228 | 269 | 228 | 190 |
| Cu Peel | 7.92 | 7.62 | 7.33 | 7.42 |
| Water Uptake (%) | 0.196 | 0.27 | 0.25 | 0.26 |
| Solder Dip @ 550 F. | 100 | 100 | 100 | 100 |
| (% Pass) | | | | |
| K1C (MPa · m^{0.5}) | 1.02 | | 1.06 | |
| G1C (kJ/m²) | 0.44 | n/d | 0.46 | n/d |
| UL94 Rating | V-0 | V-0 | V-0 | V-0 |

All the tougheners did not negatively impact the glass transition temperature significantly. A depression of the T_{g} was observed with the use of the core shell rubber D (the CSR from which excess surfactant had been removed). The core shell rubber C to which a Byk-A™ 530 defoaming aid was added also exhibited a T_{g} depression as shown in Table 7. However, the magnitudes of T_{g} depression are not significant. Defoaming aids were added to improve prepreg appearance. However, for core shell rubber D, no T_{g} difference was observed with or without the addition of the defoamer.

1. A masterblend comprising:
a) a solvent; and
b) a core shell rubber wherein the masterblend does not contain a thermosetting resin.

2. A masterblend in accordance with claim 1 wherein said core shell rubber has a styrene butadiene core and wherein said styrene butadiene core does not swell in said solvent.

3. A masterblend in accordance with claim 1 wherein said core shell rubber has a methyl methacrylate shell.

4. A masterblend in accordance with claim 1 wherein said solvent is selected from the group consisting of methyl ethyl ketone, acetone, Dowanol™ PM, cyclohexanone, Dowanol™ PMA, dimethylformamide, methyl isobutyl ketone, xylene, toluene, methanol, butanol, and combinations thereof.

5. A masterblend in accordance with claim 1 wherein said masterblend comprises from 5 weight percent to 40 weight percent core shell rubber, based on the total weight of the masterblend.

6. A process comprising:
a) dispersing a core shell rubber in a solvent in a dispersion zone to form a masterblend; and
b) admixing the masterblend with a thermosetting resin to form a curable composition.

7. A process in accordance with claim 6 wherein said dispersion zone comprises a high shear mixer capable of generating a power per unit mass of at least 0.5 W/Kg.

8. A varnish prepared from the masterblend of claim 1.

9. A prepreg prepared from the varnish of claim 8.

10. An electrical laminate prepared from the varnish of claim 8.

11. A printed circuit board prepared from the varnish of claim 8.

12. A coating prepared from the varnish of claim 8.

13. A composite prepared from the varnish of claim 8.

14. A casting prepared from the varnish of claim 8.

15. An adhesive prepared from the varnish of claim 8.
